(19) United States
(12) Patent Application Publication
(10) Pub. No.: US 2018/0292462 A1
(43) Pub. Date: Oct. 11, 2018

(54) STATE OF CHARGE CALCULATION APPARATUS FOR SECONDARY BATTERY AND STORAGE BATTERY SYSTEM

(71) Applicant: CALSONIC KANSEI CORPORATION, Saitama-shi, Saitama (JP)

(72) Inventor: Kinnosuke ITABASHI, Saitama-shi, Saitama (JP)

(73) Assignee: CALSONIC KANSEI CORPORATION, Saitama-shi, Saitama (JP)

(21) Appl. No.: 15/570,896

(22) PCT Filed: Apr. 22, 2016
(86) PCT No.: PCT/JP2016/002163

§ 371 Date: Oct. 31, 2017

(30) Foreign Application Priority Data
May 1, 2015 (JP) 2015-094388

(51) Int. Cl. G01R 31/36; H01M 10/48; H01M 10/42; H01M 10/44

(52) U.S. Cl. CPC G01R 31/3648; H01M 10/482; H01M 2010/4271; H01M 10/441; H01M 10/425

(57) ABSTRACT

A state of charge calculation apparatus and storage battery system improve the estimation accuracy of the state of charge of a secondary battery. A state of charge calculation apparatus (15) for a secondary battery (14) includes a charging/discharging current detector (22) that detects a charging/discharging current of the secondary battery (14), a terminal voltage detector (23) that detects a terminal voltage of the secondary battery (14), a first estimator (24) that integrates the charging/discharging current and estimates a first state of charge, a second estimator (25) that estimates a second state of charge on the basis of the relationship between open circuit voltage and state of charge of the secondary battery (14), and a state of charge calculator (26) that calculates a third state of charge on the basis of the first state of charge and second state of charge respectively weighted by the charging/discharging current.

### CROSS-REFERENCE TO RELATED APPLICATION

This application claims priority to and the benefit of Japanese Patent Application No. 2015-094388 filed May 1, 2015, the entire contents of which are incorporated herein by reference.

### TECHNICAL FIELD

This disclosure relates to a state of charge calculation apparatus that calculates the state of charge of a secondary battery used, for example, in a hybrid vehicle. This disclosure also relates to a storage battery system.

### BACKGROUND

Conventionally, secondary batteries that can be charged and discharged have been used in vehicles such as hybrid vehicles. The state of charge (SOC) of the secondary battery needs to be detected to ascertain the distance the vehicle can travel, for example.

Since the state of charge cannot be detected directly, known methods estimate the state of charge using a current integration method (coulomb counting method) or an open circuit voltage estimation method (consecutive parameter method), as in patent literature (PTL) 1. The current integration method estimates the absolute state of charge (ASOC) by detecting the charging/discharging current of the secondary battery over time and integrating the current. The open circuit voltage estimation method estimates the relative state of charge (RSOC) by estimating the open circuit voltage of the battery using an equivalent circuit model of the battery.

### CITATION LIST

### Patent Literature

PTL 1: JP 2005-201743 A

### SUMMARY

(Technical Problem)

Since error of the current sensor accumulates with the current integration method, however, the estimation accuracy of the state of charge has room for improvement. With the open circuit voltage estimation method, the open circuit voltage (OCV) is calculated as OCV=V+(I×R), where V is the measured terminal voltage, I is the measured charging/discharging current, and R is the estimated internal resistance. Here, if the charging/discharging current I is relatively large, as when charging with a large current, then the contribution of error in the estimated internal resistance R increases, leaving room for improvement in the estimation of the open circuit voltage and the state of charge.

In light of these considerations, it would therefore be helpful to provide a state of charge calculation apparatus and a storage battery system that can improve the estimation accuracy of the state of charge of a secondary battery.

(Solution to Problem)

A state of charge calculation apparatus according to a first aspect of this disclosure includes:

a charging/discharging current detector configured to detect a charging/discharging current of a secondary battery;

a terminal voltage detector configured to detect a terminal voltage of the secondary battery;

a first estimator configured to integrate the charging/discharging current and estimate a first state of charge;

a second estimator configured to estimate a second state of charge on the basis of a relationship between an open circuit voltage and a state of charge of the secondary battery; and

a state of charge calculator configured to calculate a third state of charge on the basis of the first state of charge and the second state of charge respectively weighted by the charging/discharging current.

In a state of charge calculation apparatus according to a second aspect of this disclosure, the state of charge calculator is preferably configured to calculate the third state of charge on the basis of the first state of charge and the second state of charge respectively weighted by a charging/discharging rate yielded by dividing the charging/discharging current by a battery capacity of the secondary battery.

In a state of charge calculation apparatus according to a third aspect of this disclosure, a weighting for the second state of charge is preferably smaller as the charging/discharging rate is greater.

In a state of charge calculation apparatus according to a fourth aspect of this disclosure, the second estimator is preferably further configured to estimate a fully charged capacity of the secondary battery, and the state of charge calculator is preferably configured to calculate the charging/discharging rate using the estimated fully charged capacity as the battery capacity.

A storage battery system according to a fifth aspect of this disclosure includes:

a lead storage battery;

a secondary battery having a voltage substantially equivalent to a voltage of the lead storage battery and being connected in parallel to the lead storage battery, the secondary battery not being a lead storage battery; and

a state of charge calculation apparatus configured to calculate a state of charge of the secondary battery,

wherein the state of charge calculation apparatus comprises:
a charging/discharging current detector configured to detect a charging/discharging current of the secondary battery;
a terminal voltage detector configured to detect a terminal voltage of the secondary battery;
a first estimator configured to integrate the charging/discharging current and estimate a first state of charge;
a second estimator configured to estimate a second state of charge on the basis of a relationship between an open circuit voltage and a state of charge of the secondary battery; and
a state of charge calculator configured to calculate a third state of charge on the basis of the first state of charge and the second state of charge respectively weighted by the charging/discharging current.

(Advantageous Effect)

With the state of charge calculation apparatus according to the first aspect of this disclosure, the first weighting coefficient a and the second weighting coefficient β are determined on the basis of the charging/discharging current i(k) of the first secondary battery. The third state of charge SOC3(k) is then ultimately calculated on the basis of the weighted first state of charge αSOC1(k) and the weighted second state of charge βSOC2(k). As described above, the estimation accuracy of the second state of charge SOC2(k) using the open circuit voltage estimation method differs in accordance with the value of the charging/discharging current i(k). Accordingly, by weighting on the basis of the charging/discharging current i(k) as described above, the estimation accuracy of the state of charge of the first secondary battery increases.

With the state of charge calculation apparatus according to the second aspect of this disclosure, weighting is performed in accordance with the charging/discharging rate C(k) yielded by dividing the charging/discharging current i(k) by the battery capacity of the first secondary battery (the design capacity DC or the fully charged capacity FCC(k)). Therefore, the first lookup table and the second lookup table can be used in common for example in a plurality of storage battery systems 10 that use the same type of secondary batteries with different battery capacities as the first secondary battery, thereby reducing development costs.

With the state of charge calculation apparatus according to the third aspect of this disclosure, the second weighting coefficient β, by which the second state of charge SOC2(k) is multiplied, is set to decrease as the charging/discharging current i(k) or the charging/discharging rate C(k) is larger. This results in a smaller degree of contribution of the second state of charge SOC2(k), for which the estimation accuracy decreases when the charging/discharging current i(k) is relatively large, as described above. Hence, the estimation accuracy of the state of charge of the first secondary battery is further improved.

With the state of charge calculation apparatus according to the fourth aspect of this disclosure, the charging/discharging rate C(k) is calculated using the estimated fully charged capacity FCC(k) as the battery capacity. Therefore, the estimation accuracy of the charging/discharging rate C(k) increases as compared to when the design capacity DC is used, thereby further improving the estimation accuracy of the state of charge of the first secondary battery.

With the storage battery system according to the fifth aspect of this disclosure, the first weighting coefficient α and the second weighting coefficient β are determined on the basis of the charging/discharging current i(k) of the first secondary battery. The third state of charge SOC3(k) is then ultimately calculated on the basis of the weighted first state of charge αSOC1(k) and the weighted second state of charge βSOC2(k). As described above, the estimation accuracy of the second state of charge SOC2(k) using the open circuit voltage estimation method differs in accordance with the value of the charging/discharging current i(k). Accordingly, by weighting on the basis of the charging/discharging current i(k) as described above, the estimation accuracy of the state of charge of the first secondary battery increases.

### BRIEF DESCRIPTION OF THE DRAWINGS

In the accompanying drawings:

FIG. 1 is a block diagram illustrating the configuration of a storage battery system according to Embodiment 1 of this disclosure;

FIG. 2 is a block diagram illustrating the configuration of the state of charge calculation apparatus in FIG. 1;

FIG. 3 is a block diagram illustrating the configuration of the state of charge calculator in FIG. 2;

FIG. 4 illustrates the relationship between a coefficient and the current or the charging/discharging rate in a first lookup table; and

FIG. 5 illustrates the relationship between a coefficient and the current or the charging/discharging rate in a second lookup table.

### DETAILED DESCRIPTION

The following describes embodiments of this disclosure.

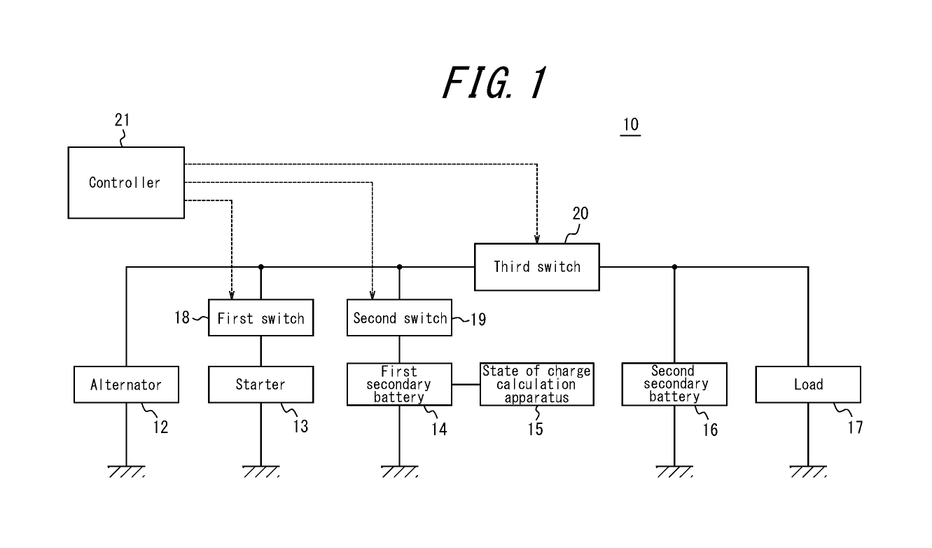

First, the configuration of a storage battery system 10 according to an embodiment of this disclosure is described with reference to FIG. 1. The storage battery system 10 is mounted in a vehicle such as a hybrid electric vehicle (HEV).

The storage battery system 10 includes an alternator 12, a starter 13, a first secondary battery 14, a state of charge calculation apparatus 15, a second secondary battery 16, a load 17, a first switch 18, a second switch 19, a third switch 20, and a controller 21. The alternator 12, starter 13, first secondary battery 14, second secondary battery 16, and load 17 are connected in parallel.

The alternator 12 is an electrical generator and is connected mechanically to the vehicle's engine. The alternator 12 can generate electricity by being driven by the engine. The output voltage of the electrical power that the alternator 12 generates by being driven by the engine is adjusted by a regulator, and the electrical power is supplied to the first secondary battery 14, the second secondary battery 16, the load 17, and auxiliary equipment in the vehicle. The alternator 12 can also generate electricity by regeneration, for example when the vehicle slows down. The electrical power that the alternator 12 generates by regeneration is used to charge the first secondary battery 14 and the second secondary battery 16.

The starter 13 is, for example, configured to include a cell motor, receives a power supply from at least one of the first secondary battery 14 and the second secondary battery 16, and starts the engine of the vehicle.

The first secondary battery 14 is a secondary battery other than a lead storage battery, such as a lithium-ion battery or a nickel-hydrogen battery. In this embodiment, the output voltage of the first secondary battery 14 is substantially equal to the output voltage of the second secondary battery 16 and is, for example, 12 V. Alternatively, the output voltage of the first secondary battery 14 may differ from the output voltage of the second secondary battery 16. In this case, the output voltage of the first secondary battery 14 is adjusted by a DC/DC converter to be substantially equal to the output voltage of the second secondary battery 16. The first secondary battery 14 can supply power to auxiliary equipment including the starter 13, to the load 17, to an ECU, and the like while driving of the engine is suspended (during suspension of idling).

The state of charge calculation apparatus 15 calculates the state of charge of the first secondary battery 14. Details on the state of charge calculation apparatus 15 are provided below.

The second secondary battery 16 is a lead storage battery that has an output voltage that is, for example, a nominal voltage of 12 V. The second secondary battery 16 can supply the load 17 with electrical power.

The load 17 is a load that, for example, includes the audio, air-conditioning, navigation system, and the like provided in the vehicle. The load 17 operates by consuming the supplied electrical power. The load 17 operates by receiving the electrical power supplied from the first secondary battery 14 and the second secondary battery 16 while driving of the engine is suspended and operates by receiving the electrical power supplied from the alternator 12, the first secondary battery 14, and the second secondary battery 16 during driving of the engine.

The first switch 18 is a switch that connects in series with the starter 13. The first switch 18 connects or disconnects the starter 13 in parallel with other constituent elements.

The second switch 19 is a switch that connects in series with the first secondary battery 14. The second switch 19 connects or disconnects the first secondary battery 14 in parallel with other constituent elements.

The third switch 20 is a switch that connects in series with the second secondary battery 16 and the load 17. The third switch 20 connects or disconnects the second secondary battery 16 and the load 17 in parallel with other constituent elements.

The controller 21 is, for example, configured to include the ECU provided in the vehicle and controls the overall operations of the storage battery system 10. For example, the controller 21 controls the operations of the first switch 18, the second switch 19, and the third switch 20 to supply electrical power with the alternator 12, the first secondary battery 14, and the second secondary battery 16 and to charge the first secondary battery 14 and the second secondary battery 16.

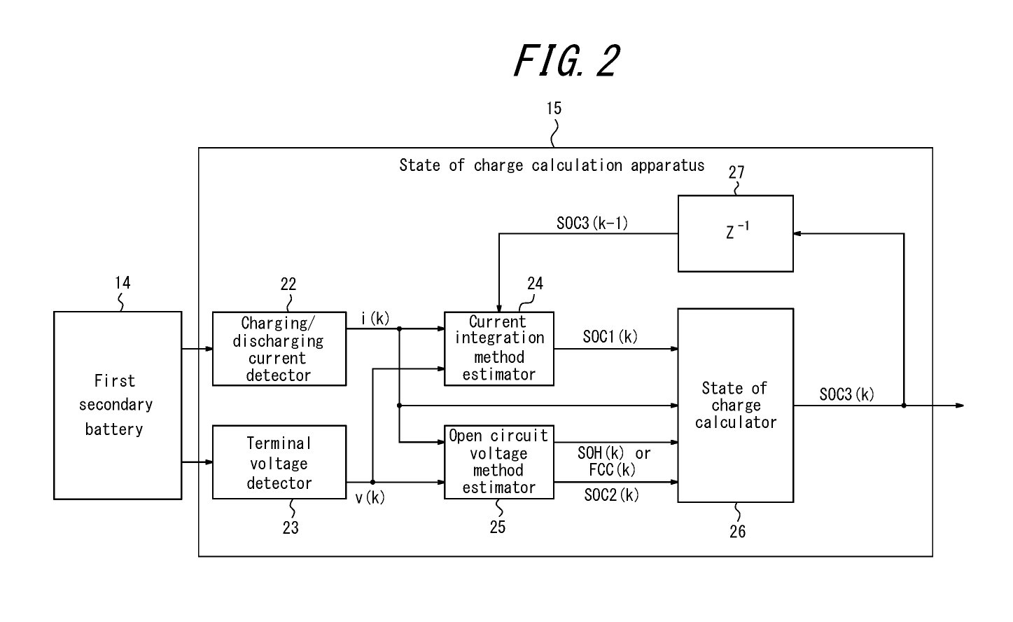

Next, details on the state of charge calculation apparatus 15 are provided with reference to FIG. 2. The state of charge calculation apparatus 15 includes a charging/discharging current detector 22, a terminal voltage detector 23, a current integration method estimator (first estimator) 24, an open circuit voltage method estimator (second estimator) 25, a state of charge calculator 26, and a delay element 27.

The charging/discharging current detector 22 is, for example, configured to include a shunt resistor and detects the charging/discharging current i(k) of the first secondary battery 14. Here, k indicates the time in discrete time. The charging/discharging current i(k) is taken as the absolute value of the charging/discharging current. The detected charging/discharging current i(k) is input into the current integration method estimator 24, the open circuit voltage method estimator 25, and the state of charge calculator 26 as an input signal. The charging/discharging current detector 22 is not limited to the above configuration and may adopt a variety of structures and forms as appropriate.

The terminal voltage detector 23 detects the terminal voltage v(k) of the first secondary battery 14. The detected terminal voltage v(k) is input into the current integration method estimator 24 and the open circuit voltage method estimator 25 as an input signal. The terminal voltage detector 23 is not limited to the above configuration and may adopt a variety of structures and forms as appropriate.

The current integration method estimator 24 estimates the current integration method state of charge (first state of charge) SOC1(k). Details are provided below. For example, the initial starting of the vehicle (engine) is set to time k=0, and the state of the first secondary battery 14 at time k=0 is assumed to be stable and without load. In this case, the terminal voltage v(0) input from the terminal voltage detector 23 can be considered the open circuit voltage OCV(0). Therefore, the current integration method estimator 24 estimates the first state of charge SOC1(0) to be the state of charge corresponding to the value of the terminal voltage v(0) considered to be the open circuit voltage OCV(0) by using an OCV-SOC lookup table, which is calculated in advance by experiment or simulation and which indicates the relationship between the open circuit voltage and the state of charge of the first secondary battery 14. The first state of charge SOC1(0) is input into the state of charge calculator 26 as an input signal. As described below, at time k≥1, the current integration method estimator 24 estimates the first state of charge SOC1(k) to be the value yielded by adding the charging/discharging current i(k) input from the charging/discharging current detector 22 to the previous value SOC3(k−1) of a third state of charge input from the delay element 27. The estimated first state of charge SOC1(k) is input into the state of charge calculator 26 as an input signal.

The open circuit voltage method estimator 25 estimates the open circuit voltage method state of charge (second state of charge) SOC2(k). Specifically, the open circuit voltage method estimator 25 first estimates parameters in an equivalent circuit model of the first secondary battery 14, such as a Foster-type RC ladder circuit or a Cauer-type RC ladder circuit, on the basis of the charging/discharging current i(k) and the terminal voltage v(k) input respectively from the charging/discharging current detector 22 and the terminal voltage detector 23. For example, the open circuit voltage method estimator 25 estimates the capacitance C(k) of a capacitor, the internal resistance R(k), and the open circuit voltage OCV(k) using an adaptive filter, such as a Kalman filter, or the least-squares method. Here, the open circuit voltage OCV(k) is, for example, calculated as OCV(k)=v(k)+(i(k)×R(k)). The open circuit voltage method estimator 25 estimates the second state of charge SOC2(k) to be the state of charge corresponding to the value of the open circuit voltage OCV(k) by using an OCV-SOC lookup table, which is calculated in advance by experiment or simulation and which indicates the relationship between the open circuit voltage and the state of charge of the first secondary battery 14. The estimated second state of charge SOC2(k) is input into the state of charge calculator 26 as an input signal.

On the basis of the relationship between the internal resistance of the first secondary battery 14 and the state of health (SOH), the open circuit voltage method estimator 25 preferably further estimates the state of health SOH(k). Specifically, the open circuit voltage method estimator 25 estimates the state of health SOH(k) to be the state of health corresponding to the internal resistance R(k) using an R-SOH lookup table, which is calculated in advance by experiment or simulation and which indicates the relationship between the internal resistance and the state of health of the first secondary battery 14. The state of health SOH(k) is a parameter indicating the degree of degradation of the battery and is represented by SOH(k)=FCC(k)/DC, where DC (a constant) is the design capacity, and FCC(k) is the fully charged capacity. The estimated state of health SOH(k), or the fully charged capacity FCC(k) yielded by multiplying the state of health SOH(k) by the design capacity DC, is input into the state of charge calculator 26 as an input signal.

The state of charge calculator 26 calculates the third state of charge SOC3(k) on the basis of a first state of charge αSOC1(k) and a second state of charge βSOC2(k) that are respectively weighted using a first weighting coefficient a and a second weighting coefficient β based on the charging/discharging current i(k). The state of charge calculator 26 preferably calculates the third state of charge SOC3(k) on the basis of a first state of charge αSOC1(k) and a second state of charge βSOC2(k) that are respectively weighted using a first weighting coefficient a and a second weighting coefficient β based on the charging/discharging current i(k) and the battery capacity (the design capacity DC or the fully charged capacity FCC(k)). In this embodiment, the third state of charge SOC3(k) is determined to be the state of charge of the first secondary battery 14 at time k. Details on the state of charge calculator 26 are provided below.

Upon receiving input of the third state of charge SOC3(k) from the state of charge calculator 26, the delay element 27 inputs the previous value SOC3(k−1) of the third state of charge to the current integration method estimator 24.

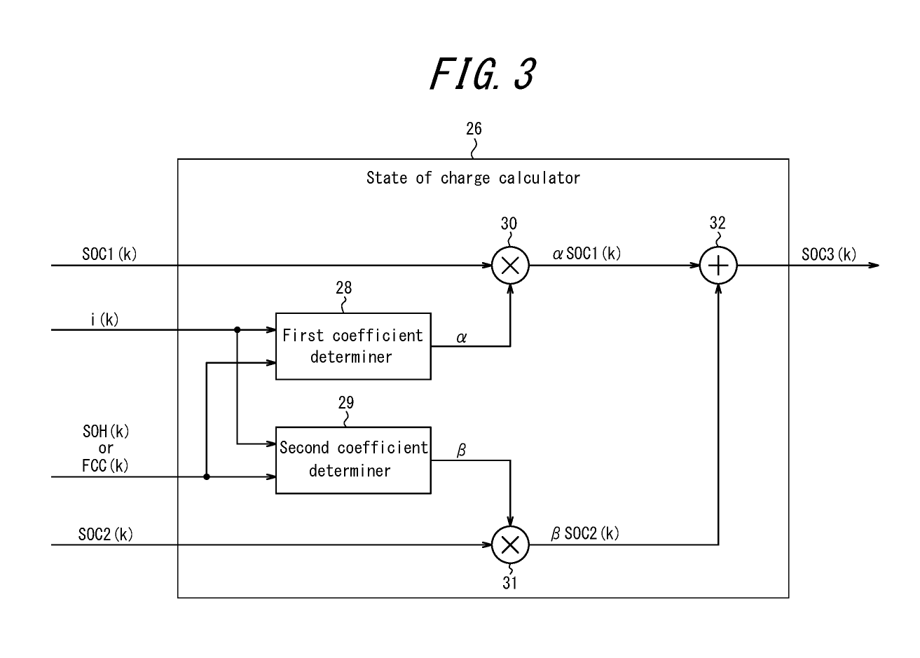

Next, details on the state of charge calculator 26 are provided with reference to FIG. 3. The state of charge calculator 26 includes a first coefficient determiner 28, a second coefficient determiner 29, a first multiplier 30, a second multiplier 31, and an adder 32.

On the basis of the charging/discharging current i(k), the first coefficient determiner 28 determines the first weighting coefficient a by which the first state of charge SOC1(k) is multiplied. Specifically, the first coefficient determiner 28 uses the predetermined first lookup table that indicates the relationship between the current and the coefficient to determine the first weighting coefficient a to be the coefficient corresponding to the charging/discharging current i(k). The first coefficient determiner 28 preferably determines the first weighting coefficient a in accordance with a charging/discharging rate C(k) yielded by dividing the charging/discharging current i(k) by the battery capacity (the design capacity DC or the fully charged capacity FCC(k)). The charging/discharging rate C(k) is represented by C(k)=i(k)/DC or C(k)=i(k)/FCC(k), using the charging/discharging current i(k) and the battery capacity (the design capacity DC or the fully charged capacity FCC(k)). In this case, the first coefficient determiner 28 uses the predetermined first lookup table that indicates the relationship between the charging/discharging rate and the coefficient to determine the first weighting coefficient α to be the coefficient corresponding to the charging/discharging rate C(k). Details on the first lookup table are provided below. Here, the design capacity DC may be used as the battery capacity, but the fully charged capacity FCC(k) is preferably used. The fully charged capacity FCC(k) is represented by FCC(k)=SOH(k)×DC, using the state of health SOH(k) and the design capacity DC.

On the basis of the charging/discharging current i(k), the second coefficient determiner 29 determines the second weighting coefficient β by which the second state of charge SOC2(k) is multiplied. Specifically, the second coefficient determiner 29 uses the predetermined second lookup table that indicates the relationship between the current and the coefficient to determine the second weighting coefficient β to be the coefficient corresponding to the charging/discharging current i(k). The second coefficient determiner 29 preferably determines the second weighting coefficient β in accordance with the charging/discharging rate C(k). As described above, the charging/discharging rate C(k) is represented by C(k)=i(k)/DC or C(k)=i(k)/FCC(k). In this case, the second coefficient determiner 29 uses the predetermined second lookup table that indicates the relationship between the charging/discharging rate and the coefficient to determine the second weighting coefficient β to be the coefficient corresponding to the charging/discharging rate C(k). Here, the design capacity DC may be used as the battery capacity, but the fully charged capacity FCC(k) is preferably used. As described above, the fully charged capacity FCC(k) is represented by FCC(k)=SOH(k)×DC.

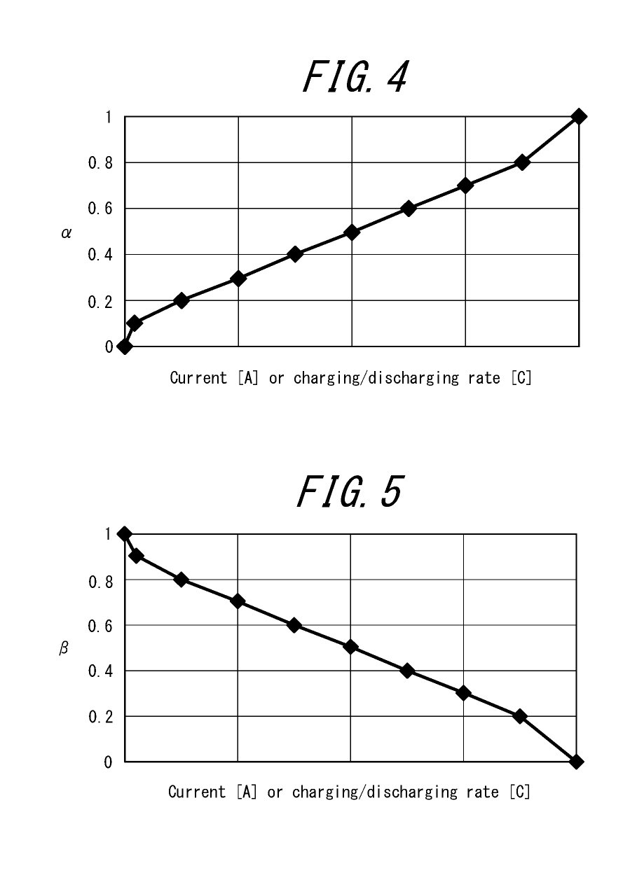

With reference to FIG. 4 and FIG. 5, the first lookup table and the second lookup table are now described.

FIG. 4 is a graph illustrating the relationship between a coefficient and the current or the charging/discharging rate in the first lookup table. In FIG. 4, the horizontal axis represents the current or charging/discharging rate, and the vertical axis represents the coefficient. As illustrated in FIG. 4, in the first lookup table, as the current or charging/discharging rate is larger, the value of the corresponding coefficient increases. In other words, as the charging/discharging current i(k) or the charging/discharging rate C(k) is larger, the weighting of the first state of charge SOC1(k) estimated by the current integration method is set to increase.

FIG. 5 is a graph illustrating the relationship between a coefficient and the current or the charging/discharging rate in the second lookup table. In FIG. 5, the horizontal axis represents the current or charging/discharging rate, and the vertical axis represents the coefficient. As illustrated in FIG. 5, in the second lookup table, as the current or charging/discharging rate is larger, the value of the corresponding coefficient decreases. In other words, as the charging/discharging current i(k) or the charging/discharging rate C(k) is larger, the weighting of the second state of charge SOC2(k) estimated by the open circuit voltage estimation method is set to decrease.

In the first lookup table and the second lookup table, the relationships between the coefficient and the current or the charging/discharging rate are set so that the sum of the coefficients established for any current or charging/discharging rate is one. Accordingly, the sum of the first weighting coefficient α and the second weighting coefficient β established for the charging/discharging current i(k) is always one.

The first multiplier 30 illustrated in FIG. 3 multiplies the first state of charge SOC1(k) by the determined first weighting coefficient a to calculate the weighted first state of charge αSOC1(k).

The second multiplier 31 multiplies the second state of charge SOC2(k) by the determined second weighting coefficient to calculate the weighted second state of charge βSOC2(k).

The adder 32 calculates the sum of the weighted first state of charge αSOC1(k) and the weighted second state of charge βSOC2(k) and sets the sum as the third state of charge SOC3(k).

In this way, with the state of charge calculation apparatus 15 according to Embodiment 1 of this disclosure, the first weighting coefficient α and the second weighting coefficient are determined on the basis of the charging/discharging current i(k) of the first secondary battery 14. The third state of charge SOC3(k) is then ultimately calculated on the basis of the weighted first state of charge αSOC1(k) and the weighted second state of charge βSOC2(k). As described above, the estimation accuracy of the second state of charge SOC2(k) using the open circuit voltage estimation method differs in accordance with the value of the charging/discharging current i(k). Accordingly, by weighting on the basis of the charging/discharging current i(k) as described above, the estimation accuracy of the state of charge of the first secondary battery 14 increases.

With the state of charge calculation apparatus 15, weighting is performed in accordance with the charging/discharging rate C(k) yielded by dividing the charging/discharging current i(k) by the battery capacity of the first secondary battery 14 (the design capacity DC or the fully charged capacity FCC(k)). Therefore, the first lookup table and the second lookup table can, for example, be used in common in a plurality of storage battery systems 10 that use the same type of secondary batteries with different battery capacities as the first secondary battery 14, thereby reducing development costs.

In the state of charge calculation apparatus 15, the second weighting coefficient β, by which the second state of charge SOC2(k) is multiplied, is set to decrease as the charging/discharging current i(k) or the charging/discharging rate C(k) is larger. This results in a smaller degree of contribution of the second state of charge SOC2(k), for which the estimation accuracy decreases when the charging/discharging current i(k) is relatively large as described above, thereby further improving the estimation accuracy of the state of charge of the first secondary battery 14.

In the state of charge calculation apparatus 15, the charging/discharging rate C(k) is calculated using the estimated fully charged capacity FCC(k) as the battery capacity. Therefore, the estimation accuracy of the charging/discharging rate C(k) increases as compared to when the design capacity DC is used, thereby further improving the estimation accuracy of the state of charge of the first secondary battery 14.

Although this disclosure is based on embodiments and drawings, it is to be noted that various changes and modifications will be apparent to those skilled in the art based on this disclosure. Therefore, such changes and modifications are to be understood as included within the scope of this disclosure. For example, the functions and the like included in the various components and steps may be reordered in any logically consistent way. Furthermore, components or steps may be combined into one or divided.

In the above embodiment, the storage battery system 10 has been described as being mounted in a hybrid vehicle, but this example is not limiting. For example, the storage battery system 10 may be mounted in an electric vehicle (EV).

In the above embodiment, the storage battery system 10 has been described as including the first secondary battery, which is a lithium-ion battery or the like, and the secondary battery, which is a lead storage battery, but this example is not limiting. For example, the storage battery system 10 may further include another secondary battery that has a different battery capacity than that of the first secondary battery or the secondary battery.

### REFERENCE SIGNS LIST

10 Storage battery system

12 Alternator

13 Starter

14 First secondary battery

15 State of charge calculation apparatus

16 Second secondary battery

17 Load

18 First switch

19 Second switch

20 Third switch

21 Controller

22 Charging/discharging current detector

23 Terminal voltage detector

24 Current integration method estimator

25 Open circuit voltage method estimator

26 State of charge calculator

27 Delay element

28 First coefficient determiner

29 Second coefficient determiner

30 First multiplier

31 Second multiplier

32 Adder

1. A state of charge calculation apparatus for a secondary battery, the state of charge calculation apparatus comprising:
a charging/discharging current detector configured to detect a charging/discharging current of a secondary battery;
a terminal voltage detector configured to detect a terminal voltage of the secondary battery;
a first estimator configured to integrate the charging/discharging current and estimate a first state of charge;
a second estimator configured to estimate a second state of charge on the basis of a relationship between an open circuit voltage and a state of charge of the secondary battery and to estimate a fully charged capacity of the secondary battery; and
a state of charge calculator configured to calculate a third state of charge by adding the first state of charge and the second state of charge respectively weighted by the charging/discharging rate yielded by dividing the charging/discharging current by the estimated fully charged capacity.

2. The state of charge calculation apparatus of claim 1, wherein weightings for the first state of charge and the second state of charge are determined using a lookup table indicating a relationship between the charging/discharging rate and a weighting coefficient.

3. The state of charge calculation apparatus of claim 1, wherein a weighting for the second state of charge is smaller as the charging/discharging rate is greater.

4. (canceled)

5. (canceled)

6. A storage battery system comprising:
a lead storage battery;
a secondary battery having a voltage substantially equivalent to a voltage of the lead storage battery and being connected in parallel to the lead storage battery, the secondary battery not being a lead storage battery; and
a state of charge calculation apparatus configured to calculate a state of charge of the secondary battery,
wherein the state of charge calculation apparatus comprises:
a charging/discharging current detector configured to detect a charging/discharging current of the secondary battery;
a terminal voltage detector configured to detect a terminal voltage of the secondary battery;
a first estimator configured to integrate the charging/discharging current and estimate a first state of charge;
a second estimator configured to estimate a second state of charge on the basis of a relationship between an open circuit voltage and a state of charge of the secondary battery and to estimate a fully charged capacity of the secondary battery; and
a state of charge calculator configured to calculate a third state of charge by adding the first state of charge and the second state of charge respectively weighted by the charging/discharging rate yielded by dividing the charging/discharging current by the estimated fully charged capacity.
